(19) United States
(12) Patent Application Publication
(10) Pub. No.: US 2001/0016273 A1
(43) Pub. Date: Aug. 23, 2001

(54) MULTILAYER CVD COATED ARTICLE AND PROCESS FOR PRODUCING SAME

(76) Inventors: KRISHNAN NARASIMHAN, BIRMINGHAM, MI (US); WILLIAM C. RUSSELL, BLOOMFIELD, MI (US)

Correspondence Address: MARY K CAMERON, VALENITE INC, 31700 RESEARCH PARK DRIVE, MADISON HEIGHTS, MI, 48071

(21) Appl. No.: 09/075,236

(22) Filed: May 8, 1998

(51) Int. Cl. B32B 9/00; C23C 16/30; C23C 16/34; C23C 16/40

(52) U.S. Cl. 428/698; 428/699; 428/701; 427/419.3; 427/419.7; 427/255.7

(57) ABSTRACT

The invention relates to a cemented carbide or ceramic article having a multilayered coating of a plurality of ultrathin CVD coating layers, and a process for producing same. Each of the ultrathin CVD coating layers has a thickness of approximately 200 nanometers or less. The multilayered coating ranges from approximately 50-400 layers, has excellent adherence and a smoothness and a hardness of at least approximately 40 GPa. The CVD coated article of the present invention exhibits improved coating properties of excellent smoothness, uniformity, toughness, hardness and abrasive wear resistance.

### FIELD OF THE INVENTION

This invention relates to tough wear resistant articles having a coating of numerous ultrathin CVD coating layers exhibiting improved coating properties and a process for producing same. More particularly, this invention relates to applying a plurality of ultrathin CVD layers to form a given thickness of coating on a substrate, such as a cemented carbide or ceramic article or cutting tool, resulting in improved coating morphology, structure, smoothness, hardness, elastic modulus, friction coefficients and wear properties.

### BACKGROUND OF THE INVENTION

Cutting operations on structural materials (e.g. metallic and non-metallic workpieces) typically involve contacting the structural material workpiece with a tough and wear resistant article (e.g. a cemented carbide or ceramic cutting tool) to remove material from and shape the workpiece. Such cutting operations generally involve the input of large amounts of energy into the removal of material from the workpiece and often employ high rotating speeds for the cutting tool or the workpiece. The energy in large measure translates into friction and heat that is mostly applied to the workpiece and the cutting tool. The heat generated often has a detrimental effect on both the workpiece and the cutting tool, such as deformation of the workpiece, poor surface finish, excessive wear of the cutting tool and loss of performance. These effects in turn are among the causes of lost productivity and increased machining costs.

It is well known in the industry to employ coatings on substrates to improve performance and productivity. Coatings on cutting tools are widely used for reducing friction, dissipating heat, improving wear resistance and extending tool life. Hard, wear resistant substrates such as steel, cemented carbide, and ceramics are often coated with several layers of material. Carbides, nitrides, oxides and carbonitrides of titanium, zirconium, boron and aluminum are popular coating substances comprising individual layers. Layers of different substances can be deposited by CVD (chemical vapor deposition), PVD (physical vapor deposition), PACVD (plasma assisted chemical vapor deposition) or other techniques or combinations of coating methods. CVD coatings, as the term is used herein, means coatings deposited on a substrate through chemical reactions between reactant gases to form the coating substance. Conventional CVD coatings have distinguishing properties, such as microscopic thermal cracks and good adherence to the substrate. PVD coatings, as used herein, means coatings deposited on a substrate by moving the coating material from a source to the substrate using physical means, such as arc evaporation of the material to be deposited or sputtering. Known PVD coatings have distinguishing properties, such as excellent smoothness and internal compressive stresses, but are generally thinner and less wear resistant than CVD coatings. Attempts to improve the wear resistance of PVD coatings led to the development of multilayered PVD coatings comprised of numerous extremely thin PVD layers. U.S. Pat. No. 5,503,912 teaches thin PVD films comprising layers of various nitrides and carbonitrides. Coatings of PVD-TiN/NbN, TiN/Ni systems, consisting of PVD multilayers are taught by X. Chu et al.: Surface and Coatings Technology, 61 (1993) pp. 251.

For high friction and heat applications, such as metal cutting, it is often desirable to use a CVD coating. CVD aluminum oxide remains the preferred coating for tools used in high speed machining of steels and cast iron due to its crater wear resistance (low dissoluton rates in Fe). CVD coatings adhere better to substrates than do coatings of the same substance generated using PVD. CVD is also more versatile than PVD in coating all surfaces and geometries of the cutting tool. PVD, due to the directional nature of the method of deposition, results in “line of sight” deposition, which leaves portions of the cutting tool uncoated. Finally, the overall thickness of a PVD coating is generally limited to approximately 1-3 microns. In comparison, CVD coating overall thickness is generally on the order of 0.5 to 20 microns. The increased coating thickness can provide extra tool life, but can also result in rougher surfaces which are deleterious to tool life. For example, conventional CVD aluminum oxide coatings thicker than approximately 3 microns grow coarse crystallites resulting in undesirable surface roughness and low toughness.

Surface roughness of coatings plays a significant part in machining applications where difficult to machine work piece materials like low carbon steel, stainless steels and certain alloyed irons tend to adhere to the cutting tool forming a cold weld junction that increases the frictional forces and causes a tremendous increase in the work piece/tool pressures. This phenomenon is also known as “built-up-edge” or “BUE” in the metal cutting industries. Poor surface finish of the work piece material can also result from the BUE failure mechanism. Asperities or sharp anchor points on the surfaces of rough coatings tend to promote the BUE phenomenon. Many cutting tool manufacturing companies have resorted to mechanical polishing of CVD coated inserts to increase smoothness for reducing friction and enhancing their performance in machining. To prevent BUE and other coating failure mechanisms, there is a constant effort among cutting tool manufacturers to develop and deposit very smooth coating layers by enhancing coating technology.

It is well established that PVD TiN coatings tend to have smooth surfaces due to extremely fine grains that can result from low temperature, non equilibrium processing. It is also known that renucleation of aluminum oxide in a multilayered CVD coating leads to grain refinement. U.S. Pat. No. 4,984,940 to Bryant et al. teaches aluminum oxide layers interspersed with TiN layers to reduce coarse grain formation. However, the number of layers in conventional CVD multilayer coatings used industrially for cutting tools range only between 3-13 layers. Attempts to apply numerous CVD layers using conventional techniques result in undesirable thickening and loss of adhesion of the coating. Problems encountered with applying numerous thin layers by CVD deposition techniques include: controlling the diffusion rate of the reactant gases, controlling the nucleation of thermodynamically unstable intermediates and the composition of the layers deposited. Conventionally deposited numerous CVD layers exhibit spalling, peeling, cracking, and loss of integrity of chipbreaker geometries. “Nosing” of cutting edges, typified by an overhanging bulge of coating on the cutting edge, is also associated with thicker CVD coatings. Known methods which deposit multiple CVD layers are limited in number of layers, smoothness of the coating achieved, how thin the layers can be made and the resulting properties and performance of the article produced. It is well understood from the theory of materials that abrasive wear, fatigue strength and fracture strength are dependent on the hardness/toughness ratio. Conventionally, improving one or the other of hardness and toughness is balanced against adverse affects on the other property. Applicants have developed a multilayered CVD coated article, having a coating of ultrathin layers, which surprisingly exhibits both increased hardness and increased toughness, and a process for producing same.

### BRIEF SUMMARY OF THE INVENTION

Applicants have now discovered a multilayered CVD coated article, possessing layers of CVD coating approaching the layer quantity, layer thickness, and coating smoothness of PVD coatings, while exhibiting the advantages of CVD coating. The advantages of ultrathin multilayered CVD coatings of the present invention for cutting tools include good adhesion, improved abrasion resistance for metal cutting, increased smoothness of the coatings (lower friction coefficients) and high resistance to crack propagation (toughness). Multiple interfaces in multilayered coatings provide areas for energy dissipation of advancing cracks, leading to crack propagation resistance. In addition, the ultrathin multilayers of the present invention provide increased grain refinement and hardness as compared to known coatings of the same composition.

It is an object of the invention to provide a new multilayered CVD coated article having numerous thin layers and exhibiting increased toughness, increased hardness, and improved abrasive wear resistance.

It is an object of the present invention to provide articles having a hard wear resistant substrate, a CVD coating bonded to the substrate, the CVD coating comprised of a first system of at least two different substances deposited in individual layers comprising at least approximately 50 layers, wherein each of the layers has a thickness of less than 200 nanometers. It is a further object of the present invention to provide articles wherein the at least two different substances are selected from the group consisting of Al2O3, ZrO2, Y2O3, AlN, cBN and nitrides, carbides and carbonitrides of metals of Groups IVa and Va. It is a yet further object of the invention to provide an article wherein the CVD coating further comprises a second system of at least two different substances deposited in individual layers, each layer comprising at least one substance selected from the group consisting of Al2O3, ZrO2, Y2O3, AlN, cBN and nitrides, carbides and carbonitrides of metals of Groups IVa and Va; wherein the second system is comprised of at least one substance different from the first system.

It is a further object of the present invention to provide articles wherein the individual layers form a first system of stratified layers, each layer having a thickness of 20-190 nm. It is an alternative object of the present invention to provide articles wherein at least two different substances form a composite structure of at least two separately identifiable phases.

It is a further object of the present invention to provide articles wherein the multilayered CVD coating has a hardness of at least approximately 40 GPa.

It is another object of the present invention to provide articles wherein a hard wear resistant substrate has a CVD coating bonded to the substrate, the CVD coating having a thickness of 0.5 to 20 microns and comprised of a plurality of layers, each of the layers having a thickness of 200 nanometers or less. It is a further object of the present invention to provide such articles having a CVD coating with a smoothness value of XslopeRq of 200 or less. It is further object of the present invention to provide articles wherein at least two different alternating CVD layers comprise TiCN and TiN. It is another further object of the present invention to provide articles wherein the plurality of layers comprises at least two different individual CVD layers, each layer comprising at least one substance selected from the group consisting of Al2O3, ZrO2, Y2O3, AlN, cBN and nitrides, carbides and carbonitrides of metals of Groups IVa and Va. It is a yet further object of the present invention to provide articles wherein one of the at least two different individual CVD layers comprises at least one substance selected from the group consisting of nitrides, carbides or carbonitrides of titanium, and a second one of the at least two different individual CVD layers comprises at least one oxide of at least one element selected from the group consisting of Al and Zr; the at least one substance and the at least one oxide being alternately deposited as CVD coatings in the form of layers wherein each layer of the substance and the oxide has a thickness of less than 200 nanometers.

It is another object of the present invention to provide a CVD method of applying a multilayered coating having ultrathin layers to a hard wear resistant article comprising the steps of a) heating the article to approximately 800-1200° C. in an atmosphere comprising hydrogen and nitrogen; b) depositing a first system of at least two different individual CVD layers, each layer comprising at least one substance selected from the group consisting of Al2O3, ZrO2, Y2O3, AlN, cBN and nitrides, carbides and carbonitrides of metals of Groups IVa and Va; c) controlling coating deposition temperatures, times and flow rates and quantity of reactants delivered per unit time, whereby each of the CVD layers comprise a thickness of less than 200 nm; and d) repeating the steps b and c approximately 25 to 200 times.

It is another object of the present invention to provide a CVD method of applying a multilayered coating having ultrathin layers to a hard wear resistant article wherein the coating deposition temperature is held substantially within ±20° C. of a selected coating deposition temperature.

It is another object of the present invention to provide a CVD method of applying a multilayered coating having ultrathin layers to a hard wear resistant article wherein the quantity of reactants delivered per unit time is at least 80% of the selected flow rate for the coating deposition process.

It is another object of the present invention to provide a CVD method of applying a multilayered coating having ultrathin layers to a hard wear resistant article wherein the CVD layers are deposited to form a composite structure of at least two separately identifiable phases.

It is further object of the present invention to provide a CVD method of applying a multilayered coating having ultrathin layers to a hard wear resistant article wherein one of the at least two CVD layers comprises at least one substance selected from the group consisting of nitrides, carbides and carbonitrides of metals of Groups IVa and Va. It is further object of the present invention to provide a CVD method of applying a multilayered coating having ultrathin layers to a hard wear resistant article wherein one of the at least two CVD layers comprises at least one substance selected from the group consisting of Al₂O₃, ZrO₂, Y₂O₃, AlN and cBN. It is a further object of the present invention to provide a CVD method of applying a multilayered coating having ultrathin layers to a hard wear resistant article wherein one of the at least two CVD layers comprises at least two co-deposited substances. It is a yet further object of the present invention to provide a CVD method of applying a multilayered coating having ultrathin layers to a hard wear resistant article including depositing a second system of at least two different individual CVD layers, each layer comprising at least one substance selected from the group consisting of Al2O3, ZrO2, Y2O3, AlN, cBN and nitrides, carbides and carbonitrides of metals of Groups IVa and Va; wherein the second system is comprised of at least one substance different from the first system.

### BRIEF DESCRIPTION OF THE DRAWINGS

FIG. 1 is a photomicrograph of an ultrathin multilayered TiCN—TiN coating according to a first embodiment of the claimed invention.

FIG. 2 is a photomicrograph of an ultrathin multilayered Al₂O₃—TiN coating according to a first embodiment of the claimed invention.

FIG. 3 is a photomicrograph of a two system coating according to a second embodiment of the claimed invention.

FIGS. 4a, 4b and 4c compare the surface morphology of the invention to that of the prior art;

FIG. 4a is a photomicrograph of one embodiment of the invention.

FIG. 4b is a photomicrograph of a prior art monolayer coating.

FIG. 4c is a photomicrograph of a prior art bilayer coating.

FIG. 5 is a graph comparing the hardness of the invention with the prior art.

FIG. 6 is a graph comparing the elastic modulus of the invention with the prior art.

FIGS. 7a and 7b are graphs comparing the flank wear of the invention with the prior art.

FIG. 8 is a graph comparing the relative abrasion resistance of coatings of the present invention with the prior art.

### DETAILED DESCRIPTION OF THE INVENTION

In accordance with the present invention a cemented carbide or ceramic article having a multilayered coating of a plurality of ultrathin CVD coating layers is provided. The coated article of the present invention exhibits improved coating properties of excellent smoothness, uniformity, toughness, hardness and abrasive wear resistance.

Substances which can be adhered to the substrate as ultrathin CVD coatings according to the present invention comprise standard materials found in known CVD coatings. Preferred substances for coatings are oxides of Al, Zr and Y; and nitrides, carbides and carbonitrides of Al, B and metals of Groups IVa and Va; and combinations thereof. The reactants used to form these substances are those standardly used in CVD processes and are known to those of ordinary skill in the art; see, U.S. Pat. No. 4,619,866 to Smith, U.S. Pat. No. 4,984,940 to Bryant et al., and U.S. Pat. No. 5,665,431 to Narasimhan. The CVD coating of the present invention comprises at least two substances. In a preferred embodiment, the at least two substances each form individual, separately identifiable ultrathin layers deposited in a selected order to form the multilayered CVD coating. In a more preferred embodiment, each ultrathin CVD coating layer consists essentially of a single substance. Increases in the number of different substances, each comprising an individual layer, will be recognized as providing a variety of configurations for the layers of the present invention. Multilayer coatings containing more than two different layers allow different permutations of given layers to be used to tailor the properties of the coating. In another preferred embodiment, a single layer may comprise a composite structure of selected substances deposited individually. Alternatively, selected substances can be co-deposited during the same deposition step, as otherwise known in the industry. A preferred combination of substances which may be co-deposited in a single layer is the combination of Al₂O₃ and ZrO₂.

The multilayered coating of the present invention is comprised of ultrathin CVD layers having an individual layer thickness of approximately 10-200 nm, preferably approximately 20-190 nm. In a more preferred embodiment, ultrathin layers have an individual layer thickness of approximately 40-120 nm, most preferably approximately 60-80 nm. The total thickness of the multilayered coating is within the range of approximately 0.5-20 microns, preferably approximately 2-16 microns. The most preferred embodiment exhibits a total thickness of the coating of approximately 4-14 microns. The desired thickness of the multilayered coating is achieved by deposition of approximately 50-400 layers of ultrathin CVD coating layers on a substrate. Preferably, the number of layers ranges from 60-200. Fewer layers, within the range 20-100 may be deposited when a desired overall coating thickness ranges from 0.5-10 microns. The number of individual layers has been found to affect the toughness and hardness of the coating. By increasing the number of layers to greater than 50 and decreasing the thickness of individual layers, the toughness and hardness of the resulting coating has been improved while maintaining the desired total coating thickness.

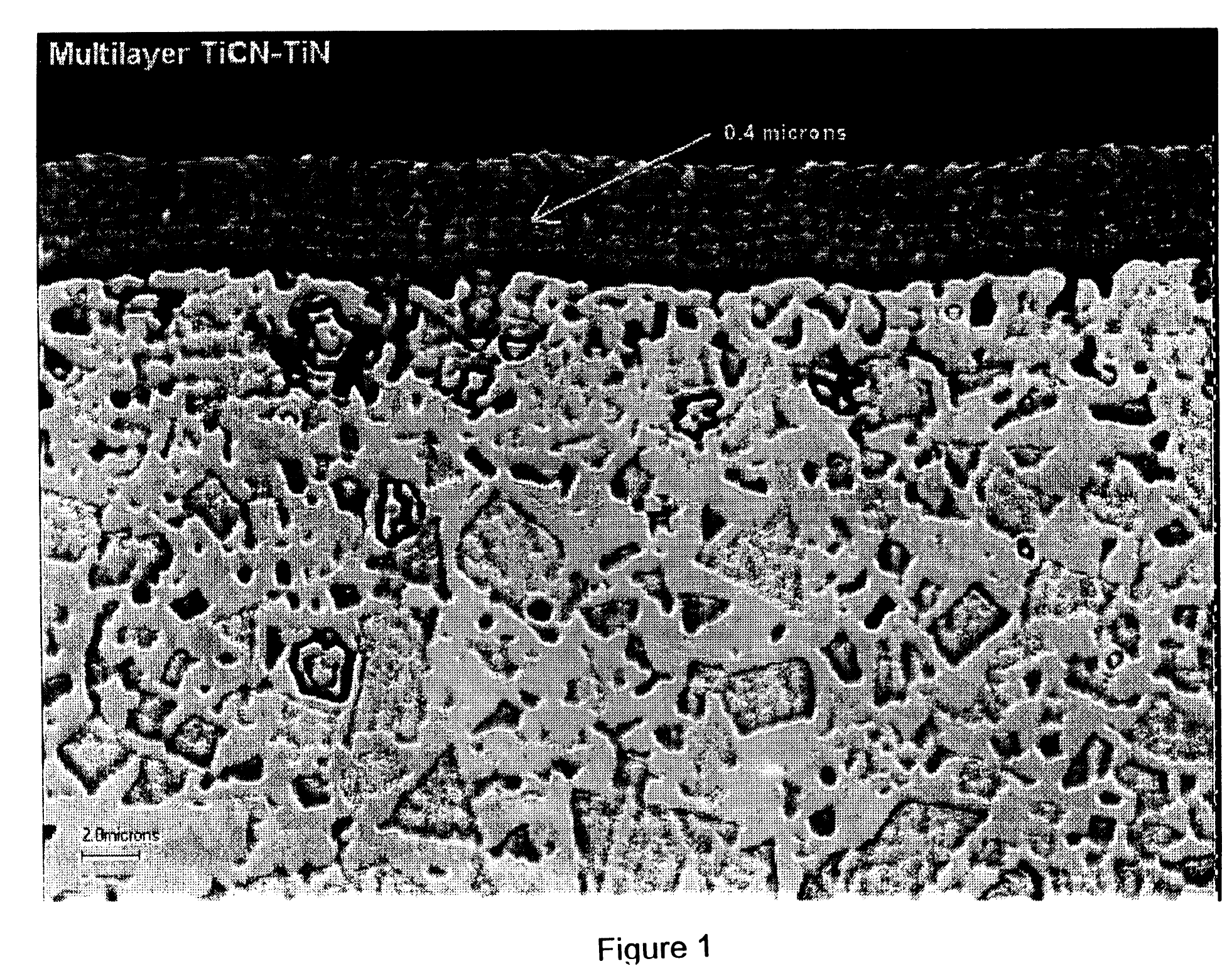

In a first embodiment of the invention, the coating comprises a selected number of ultrathin layers manifesting identifiable layer interfaces. Each layer may consist essentially of a single substance or a combination of substances in solid solution, composite or other suitably adherent form. It is preferred that each layer deposited has a uniform composition within the layer; however, it is also possible to establish a gradient within one or more layers. The multilayered coating of the present invention is formed of at least two different layers deposited in a selected order or pattern. The first embodiment relates to various configurations of such ultrathin layers, each layer of comprising at least one different substance, that are deposited upon the article to form a stratified multilayer. Several different configurations for the multilayered CVD coating have been deposited by Applicants, as exemplified in FIGS. 1, 2 and 3. Other configurations, including but not limited to, layer patterns of many different substances and multiple systems are within the scope of the present invention.

FIG. 1 shows a cross section of the ultrathin multilayered CVD coated article according to a first embodiment of the invention. This photomicrograph shows a cemented carbide article having a multilayered CVD coating of alternating layers of TiCN and TiN. The light gray background in the lower portion of FIG. 1 is the cemented carbide substrate exhibiting darker gray crystal formations of WC. In the upper portion of FIG. 1, the multilayered coating exhibits darker and lighter striations evidencing the 37 stratified layers and the identifiable interfaces of the coating. Typically a coating of TiCN appears purple or gray, depending on the C/C+N ratio, while a TiN coating appears yellow. Monolayers of either coating display no striations. The combined thickness of two layers in FIG. 1 measures approximately 0.4 microns, individual coating layers alternating between TiCN and TiN were of the order of magnitude of 0.1-0.2 microns. FIG. 1 also shows that the grain structure of the coating is extremely fine.

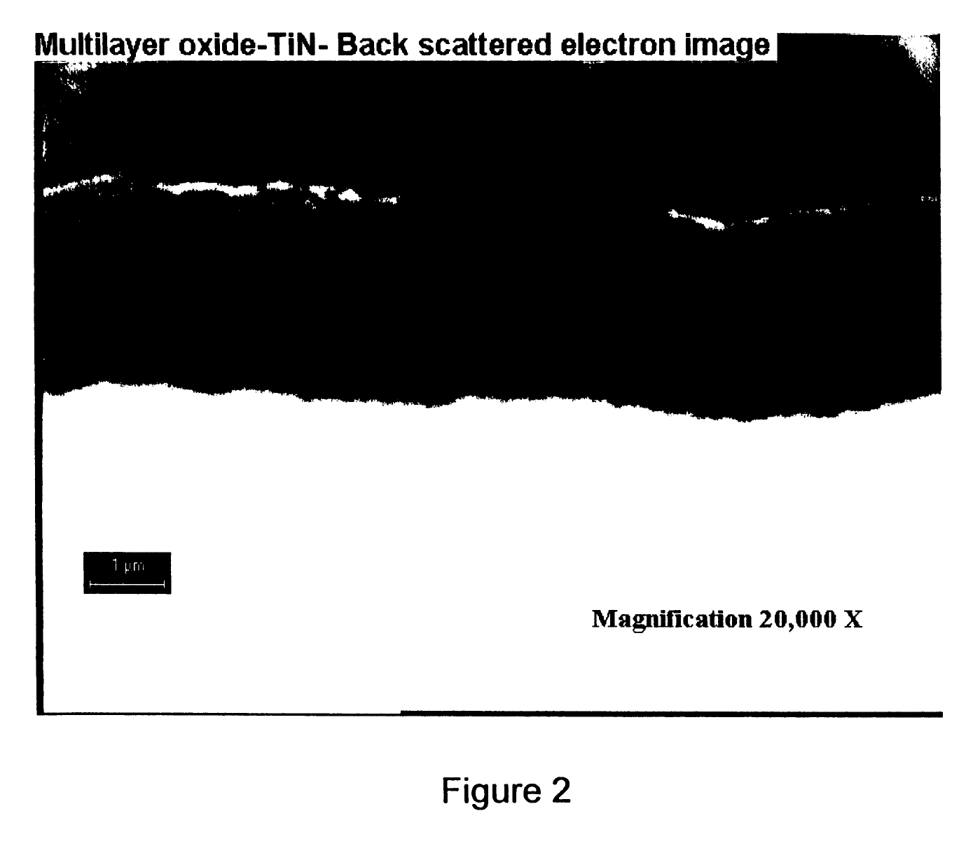

FIG. 2 shows a photomicrograph of another ultrathin multilayered coating according to the first embodiment of the claimed invention. This cross section of a cemented carbide article shows a multilayered CVD coating of alternating ultrathin layers of Al₂O₃ and TiN. The light, lower portion of FIG. 2 is the cemented carbide. The multilayered coating is shown in the upper portion of FIG. 2. The multilayered coating exhibits darker and lighter striations evidencing the stratified layers and identifiable interfaces of the coating. Typically a conventional coating of Al₂O₃ appears black. Monolayers of Al₂O₃ coating display no striations. The back scattered electron image of FIG. 2 reveals striations evidencing the 22 distinct layers which comprise the coating.

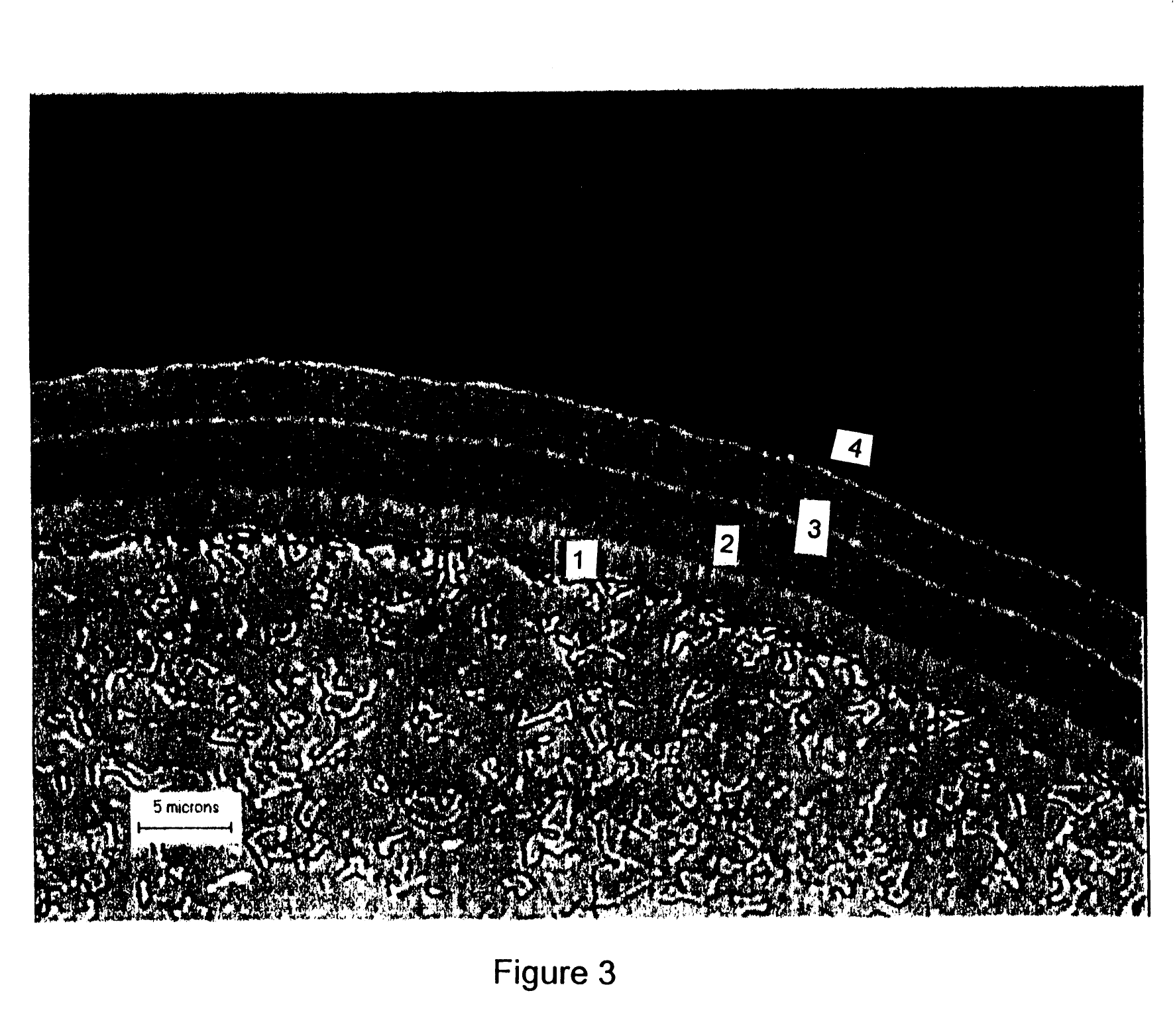

FIG. 3, is a photomicrograph of a two system coating according to a second embodiment of the present invention. In the second embodiment, two or more systems of layers according to the first embodiment comprise the coating. A single system is formed of a selected configuration of ultrathin stratified layers of two or more substances according to the first embodiment. A second system is formed of a different configuration of ultrathin stratified layers of two or more substances. The description of systems according to the present invention will become more clear upon consideration of FIG. 3. This photomicrograph shows a first multilayer system, bonded to the cemented carbide article, which comprises ultrathin layers of TiCN alternating with ultrathin layers of TiN and a second multilayer system, bonded to the first system, which comprises ultrathin layers of Al₂O₃ alternating with ultrathin layers of TiN. The second multilayer system forms the external system of the multilayered coating. The light background in the lower portion of FIG. 3 is the cemented carbide substrate exhibiting darker areas of cobalt concentration around crystal formations of WC. The multilayered coating exhibits a distinctive pattern of striations. FIG. 3 shows the first system, from the substrate outward, as a wide light band (1), and two wide dark bands (2) that are separated from each other and the outer system by narrow light bands (3). Bands (1), (2) and (3) are the TiCN layers and TiN layers of the first system. Light bands (1) and (3) indicate thicker layers of TiN. The second system of ultrathin multilayers of Al₂O₃—TiN coating forming the external system is external striated band (4), which is much darker than the other striated bands due to the Al₂O₃ layers.

In a third embodiment, some or all of the individual layers are comprised of a composite structure of two or more separate substances. Testing the limits of the thinness of the individual coating layers led Applicants to the discovery of the third embodiment. To determine the lower feasible limit on thickness for the ultrathin multilayers, Applicants deposited alternating TiCN and TiN layers using extremely rapid processing cycles of less than one minute deposition time per layer. The same deposition times were used in a separate experiment to deposit alternating Al₂O₃ and TiN layers according the present invention. Upon microscopic examination of the resulting coatings, Applicants surprisingly found that striations characteristic of the ultrathin layers of the first and second embodiments of the present invention were absent. It is believed that a composite of particles of two separate compounds forms the layer examined. The third embodiment is preferred by Applicants in applying composite layers of substances which are difficult to co-deposit, in particular those compounds which tend to form solid solutions, e.g. TiCN and TiN, and/or undesirable phases, e.g. titanium oxides are typically formed during attempted deposition of Al₂O₃ and TiN. Preferred deposition times range between 5 and 45 seconds.

The coatings of the present invention are applied using CVD processes and equipment. The apparatus used in the process of the present invention comprises an enclosed vessel of stainless steel or other suitable material having a removable top or bottom cover. The cover is removably attached to the reaction vessel by suitable means such as bolts, clamps, hinges or other means. The reaction vessel is provided with an inlet and an outlet whereby the gaseous mixture for coating enters the vessel through the inlet, flows through a reaction zone containing the substrate to be coated and exits through an outlet. Typically the vessel includes a premix area, such as a chamber, where the gases utilized are premixed at a temperature lower than the coating deposition temperature. This premix area can be internal or external to the vessel or the reaction zone. In one embodiment uniformly mixed gases exiting the premix chamber flow into the inlet and continue into the reaction zone. The apparatus is equipped with furnace controls for process parameter regulation, such as monitoring and adjusting processing time, the vessel's temperature and pressure, the temperature and pressure of the premix area, flow rate and partial pressures of gases at selected points within the apparatus. Preferably, as is typical of manufacturing level furnaces, the furnace controls can be set at selected process parameters utilizing a personal computer or other computer interface with the operator. To maintain repeatability from batch to batch, in the most preferred embodiment, the process parameters are computer controlled.

The articles, cutting tools or inserts to be coated are positioned in the reaction zone by conventional means, such as rotatable tables, trays, hooks, hangers or other fixtures known in the art. The reaction vessel includes heating elements typically in the form of graphite heating rods. The reaction vessel is loaded with articles, cutting tools or inserts to be coated and typically the vessel is flushed with a suitable inert gas such as nitrogen, argon, or the like. In a preferred embodiment of the invention, hydrogen and nitrogen comprise the atmosphere in the reaction vessel during the heating step. During the heating step, the temperature of the reaction vessel is raised to approximately 800-1200° C. Preferably, the temperature is ramped up to within the range of 900-1100° C. The pressure during the heating step can be atmospheric pressure or less. During CVD deposition steps, the pressure may be maintained at the heating step pressure or adjusted. The pressure to be selected is within the knowledge of one of ordinary skill in the art based upon the composition of the carbide or ceramic article to be coated. Typical deposition pressures are 80-200 torr, preferably 100-160 torr. However, in coating cemented carbide substrates it is preferred that pressure be maintained near atmospheric pressure to inhibit formation of brittle eta phase. Preferably, prior to introduction of the gaseous reactants, the temperature and atmosphere of the vessel are allowed to stabilize.

Gases used are those standardly employed for CVD processes, including nitrogen; halides of Al, Zr and Y; halides of metals of Groups IVa and Va; hydrogen and inert gases. Additional reactants for oxide deposition include an oxidizing gas, such as carbon mono- and di- oxides and the like. Additional reactants for carbide and carbonitride deposition include a carbon donor reactant, such as carbon tetrachloride, methane and the like. It is also within the scope of the invention to add dopant amounts of other substances, such as those recited in U.S. Pat. No. 4,619,866 and the like.

Referring now to a first embodiment of the present invention, a layer of titanium carbonitride is chemically vapor deposited on cemented carbide articles from a flowing mixture consisting essentially of gaseous reactants and inert gas. During the approximately five minute deposition time, partial pressures and flow rates of methane, nitrogen and titanium chloride carried by hydrogen are precisely controlled. Titanium chloride as used herein means TiCl, TiCl₂, TiCl₃, TiCl₄ and mixtures thereof. In a second step, reactant flow rates are adjusted to deposit an ultrathin layer of TiN. These steps are repeated until the desired number of layers of approximately 50-200, is achieved. Most, preferably, a final TiN layer is deposited for lubricity and cosmetic purposes. A purge step is the final step, but optionally may be included as an intermediate step between the first and second steps. Optionally, the methane, nitrogen and titanium chloride flows and pressures may be adjusted to achieve a desired TiCN composition and C/C+N ratio (C=Carbon, N=Nitrogen), in a manner known in the industry. In a preferred embodiment, the C/C+N ratio ranges from 0.25 to 0.65, most preferably the C/C+N ratio is 0.5-0.6. The CVD process was adjusted for the coated article of FIG. 1 to deposit extremely thin TiCN layers in the composition range C/C+N=0.25-0.50, alternating with ultrathin TiN layers.

During the deposition steps, certain process parameters are precisely controlled. The coating deposition temperature is held substantially constant, ±20° C., by control of the internal temperature and the furnace heating apparatus. Reactants may be preheated. In a preferred embodiment, the coating deposition temperature is held to within ±10° C., most preferably within ±5° C. The quantity of reactants delivered per unit time is also subjected to precise control in the process of the present invention through accurate delivery of gases and flow rate regulation. In a preferred embodiment, the quantity of reactants delivered per unit time is controlled to achieve at least 80% of the selected flow rate for said reactants for the coating deposition process, preferrably within 85-100%. In a most preferred embodiment the quantity of reactants delivered per unit time is controlled to achieve at least 95% of the selected flow rate for the reactants, preferably at least approximately 99%. The deposition time to be selected ranges from 30 seconds to 15 minutes and is a function of the other process parameters and the coating thickness desired. Cross sections of invention coatings, in FIGS. 1, 2 and 3, showed uniformity of deposition of ultrathin layers through the coating zone. This uniformity is achieved in the CVD process by precise control of parameters used, accuracy of the delivery of the reactants per unit time under conditions of rapid mass transport, controlled diffusion of reactants and repeatability of the CVD process conditions in each segment of the coating process.

The present invention will become more clear upon consideration of the following examples which are intended to be only illustrative of the present invention.

### EXAMPLES

### Example 1

A multilayer coating of alternating ultrathin layers of titanium carbonitride and titanium nitride was deposited according to the present invention. Cemented carbide inserts (0.6-1.4% cubic carbides, 12.3% Co and the remainder WC) were heated in a furnace to approximately 980° C. in an atmosphere of approximately 67 vol % hydrogen and 33 vol % nitrogen. The furnace was allowed to stabilize for approximately 1 minute. In a first deposition step, the pressure was reduced to approximately 150 torr and a hydrogen carrier gas for titanium chloride vapors was introduced. The inserts were processed, for approximately 8 minutes, in a selected flowing atmosphere of 57 liters/minute carrier gas, 25 liters/minute hydrogen, 4.8 liters/minute methane, 3 liters/minute nitrogen, and 4 liters/minute argon. In a second deposition step, the methane was turned off for 1 minute. Thereafter, the first and second deposition steps were repeated thirty times. The inserts were carburized at approximately 1100° C., slowly cooled by approximately 30° C. and a final, conventional thickness TiN layer was deposited. During processing, temperature and reactant flow rates were precisely controlled to approximately ±5° C. and approximately at least 95% of the selected flow rate, respectively. The resultant coating exhibited a multilayered structure of alternating, approximately 50-60 nm thick layers of TiCN and TiN, with an outer layer of a TiN of approximately 0.1-1.5 microns.

### Example 2

The process of Example 1 was modified as follows to produce an unstriated structure in a multilayered CVD coating of titanium carbonitride and titanium nitride. Cemented carbide inserts (0.6-1.4% cubic carbides, 12.3% Co and the remainder WC) were processed according to the first deposition step of Exhibit 1, for approximately 5 minutes. Thereafter, methane gas was pulsed off and on at intervals of 5-45 seconds, with pulses having a duration of 5-45 seconds for approximately 4 hours. A final, conventional thickness TiN layer was deposited by turning off the methane for about 15 minutes. During processing, temperature and reactant flow rates were precisely controlled to approximately ±5° C. and approximately at least 99% of the selected flow rate, respectively. The resulting coating exhibited an approximately 2 micron thick conventional layer of TiCN near the substrate, a layer containing TiCN and TiN lacking identifiable striations and an outer layer of a TiN.

### Example 3

A multilayer coating of alternating ultrathin layers of titanium nitride and aluminum oxide was deposited according to the present invention. Cemented carbide inserts (6% Co and 12% Co samples) were heated in a furnace to approximately 1000° C. in an atmosphere of approximately 99.2 vol % hydrogen and 0.8 vol % methane. The furnace was allowed to stabilize for approximately 1 minute. In a first deposition step, the pressure was reduced to approximately 150 torr and a hydrogen carrier gas for titanium chloride vapors was introduced. The inserts were processed in a flowing atmosphere of 57 liters/minute carrier gas, 25 liters/minute hydrogen, 4.8 liters/minute methane, 3 liters/minute nitrogen, and 4 liters/minute argon. After approximately 45 minutes, the reactant gases were turned off. Hydrogen flow was increased to 35 liters/minute and argon flow was increased to 10 liters/minute. In a second deposition step, a hydrogen carrier gas for aluminum chloride vapors was introduced with a flow rate of 9.5 liters/minute and the inserts were processed in a flowing atmosphere of 9.5 liters/minute carrier gas, 35 liters/minute hydrogen, 2.0 liters/minute hydrogen chloride, 1.2 liters/minute methane, 1.25 liters/minute carbon dioxide, and 10 liters/minute argon. After approximately 15 minutes, the furnace was vacuum purged. In a third deposition step, a flowing atmosphere of 24 liters/minute carrier gas for titanium chloride vapors, 12 liters/minute hydrogen, 12 liters/minute nitrogen, and 3 liters/minute argon was introduced and the inserts processed therein for approximately 5 minutes. Thereafter, the second and third deposition steps were repeated ten times. The furnace was slowly cooled by approximately 20° C. and a final, conventional thickness TiN layer was deposited. During processing, temperature and reactant flow rates were precisely controlled to approximately ±5° C. and approximately at least 95% of the selected flow rate, respectively. The resulting coating exhibited an approximately 2 micron thick conventional layer of TiCN near the substrate, a multilayered structure of alternating ultrathin layers of TiCN and Al₂O₃, each measuring approximately 120 nm thick layers, with an outer layer of a TiN of approximately 0.1-1.5 microns.

### Example 4

The process of Example 3 is modified as follows to produce a composite structure in a multilayer coating of alternating layers of titanium nitride and aluminum oxide deposited in layers. Commercially available wear resistant ceramic articles are processed according to the parameters recited in Exhibit 4, processing times are reduced by 80%. A final, conventional thickness TiN layer is deposited. During processing, temperature and reactant flow rates are precisely controlled to approximately ±5° C. and approximately at least 99% of the selected flow rate, respectively. The resulting coating exhibits an approximately 2 micron thick conventional layer of TiCN near the substrate, a layer containing TiN and Al₂O₃ lacking identifiable striations, and an outer layer of a TiN.

The coating properties of multilayered coatings according to the present invention were compared to conventional monolayered coatings and multilayered coatings. Applicants evaluated the relative mechanical and physical properties of the coatings including microstructural features, morphology, surface features, hardness, elastic modulus, abrasion resistance, and smoothness in the following Examples.

### Example 5

A multilayered TiCN/TiN coating of the present invention, a conventional bilayered TiCN/TiN were deposited on standard grade cemented carbide tools, and were compared to a standard grade monolayer TiN coated cemented carbide tool. A standard 6% cobalt cemented carbide was used as a substrate to evaluate the coatings. All CVD coatings were deposited in conventional CVD coating furnaces with graphite heating elements (hot wall reactor). A 37 layer TiCN/TiN coating was deposited according to the process of Example 1, with adjusted deposition times providing individual layer thicknesses of 100 nm. During processing, temperature and reactant flow rates were precisely controlled to approximately ±5° C. and approximately at least 85% of the selected flow rate, respectively. The bilayered and monolayered coatings were deposited using conventional CVD processes. The terminating layer for all three coatings was TiN. Table 1 summarizes the various CVD coating designs used for comparing properties.

TABLE 1

| | | Number | Individual | Total |
|---|---|---|---|---|
| | Coating sequence | of | layer | coating |
| | starting from | coating | thickness | thickness |
| Tool | substrate | layers | in microns | in microns |
| Multilayered | TiCN/TiN | 37 | ˜0.1 | 3.75 |
| | Alternating layers | | micron | |
| Prior Art | TiN | 1 | 6 microns | 6.0 |
| Monolayer** | | | | |
| Prior Art | TiCN/Tin | 2 | 3 mic. TiCN | 3.5 |
| Bilayer | | | 0.5 mic. | |
| | | | TiN | |

**Standard tool

The coatings described in Table 1 showed good adhesion in the standard Revetest scratch tester. Optical observations did not reveal any signs of delamination of the test coatings after deposition. The multilayered coatings of the present invention displayed excellent bonding between the layers.

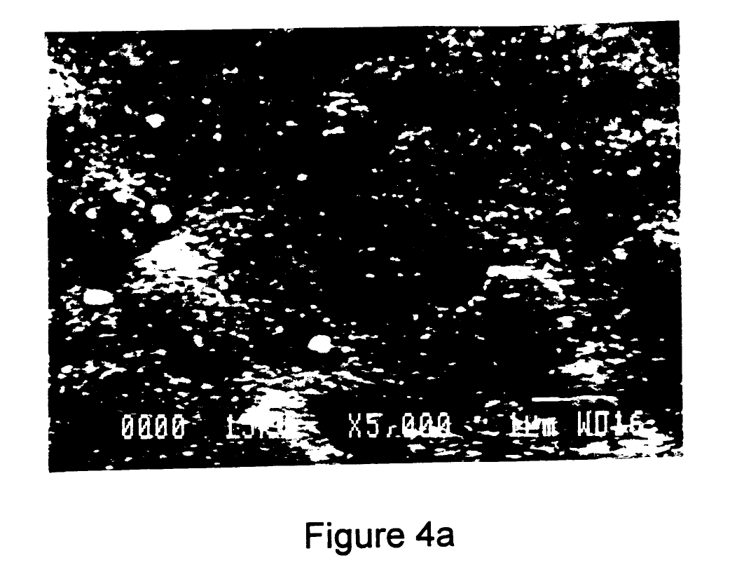

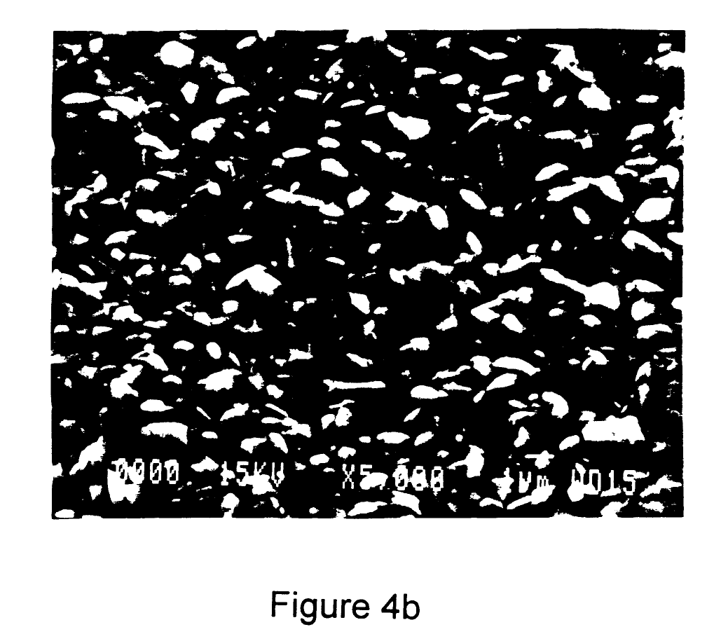

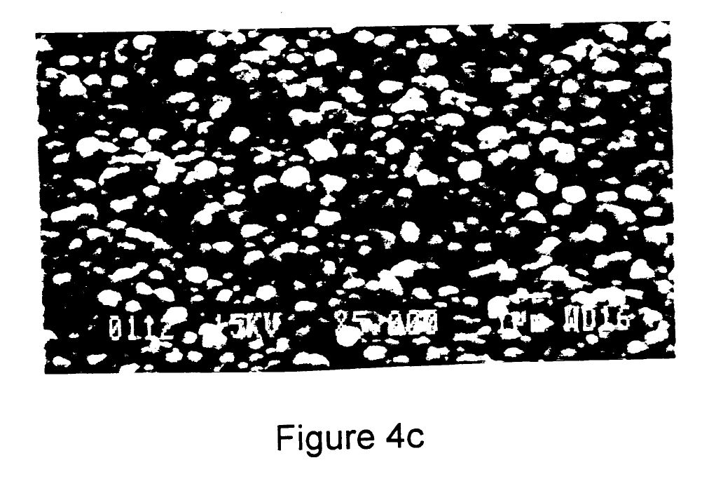

Scanning electron microscopy was used to evaluate the surface grain morphology and grain size of the CVD coatings of Table 1. Since the outer terminating layer of all the coatings was composed of TiN, the coatings shown in FIGS. 4a, 4b and 4c reveal the morphology of TiN influenced by the supporting layers of the underlying coating.

### Example 6

Hardness and elastic modulus properties of the coatings of Table 1 were measured using nanoindentation techniques. An additional multilayer TiCN/TiN coating according to Example 1 and having a C/C+N ratio of 0.5-0.6 and 62 layers was also tested (identified as “Higher carbon multilayer” in FIGS. 5 and 6). The nanoindentation measuring device obtained mechanical properties from simple measurements of load, displacement and time. Load and displacement data were obtained by driving a sharp diamond indenter (Berkovich diamond-three sided pyramidal indenter) into and then withdrawing it from the coating. The ability to produce and measure very small loads (<20 mN) and shallow depths (<250 nm) is inherent in the nanoindenter. A capacitive sensor measured the indenter shaft displacement. Further details of the nanoindentation techniques used are outlined in L. Riester and M. K. Ferber: Plastic deformation of Ceramics Ed. R. C. Bradt, Plenum press New York (1995) pp. 186-194.

Polished cross sections of the coated samples were tested with the nanoindentation measuring device. Polished cross sectioned samples revealed clearly defined coating surfaces for receiving the indentations. Ten to fifteen indents at an average spacing of 3-4 microns were made for each sample along the length of the coating. The size of the indents were in the range of 1 micron or less. Some of the indents fell outside the coating range and were not considered for the data analysis. For each indentation, the surface was located by lowering the indent at a constant rate and detecting a change in velocity on contact with the surface. In the testing mode, the load was incremented upon contact in order to maintain a constant velocity. Typical rates were 3 nm/sec. Indentations were obtained for samples at depths of penetration between approximately 30-250 nm. Only indentations that fell towards the core of the coating thickness were considered for evaluation. Others were ignored due to substrate and edge effects that could bias the measurements.

### Example 7

The coatings of Table 1 were applied to a standard carbide grade SEHN 42 AFSN style insert and evaluated for flank wear. A workpiece of 316 stainless steel, having a Brinell Hardness of approximately 160, was dry cut with a 3 inch fly milling cutter having 6 teeth. Parameters used were depth of cut 0.01 inch, feed rate 0.01 inch. feed per tooth, speed 300 surface feet per minute. After every second cut, the flank wear was measured and plotted as shown in FIG. 7a for each coated sample tested.

### Example 8

The monolayered and bilayered prior art coatings of Table 1, and a multilayered coating of the present invention were applied to a standard carbide grade SEHN 42 AFSN style insert and evaluated for flank wear against a commercially available TiCN—Al₂O₃ multilayered CVD coated grade (identified as “**1” in FIG. 7b). The multilayer TiCN/TiN coating of the present invention was applied according to Example 1 and had a C/C+N ratio of 0.5-0.6 and 49 layers (identified as “Higher carbon multilayer” in FIG. 7b). A workpiece of 1060 stainless steel, having a Brinell Hardness of approximately 163-174, was dry cut with a 3 inch fly milling cutter having 6 teeth. Parameters used were depth of cut 0.01 inch, feed rate 0.01 inch. feed per tooth, speed 600 surface feet per minute. After the first cut and at five cut intervals, the flank wear was measured and plotted as shown in FIG. 7b for each coated sample tested.

### Example 9

Testing for abrasion resistance at room temperature was conducted on multilayered coatings of the present invention and the prior art. Samples of the prior art tested were a commercially available TiCN—Al₂O₃—TiN multilayer and the bilayer TiCN—TiN of Table 1. Samples of the present invention tested were the multilayered TiCN—Al₂O₃—TiN of Example 3. The test was performed using a diamond pin on disk Tribometer under dry, sliding wear conditions. Coated samples were in the shape of a disk 60 mm in diameter and 12.5 mm thick. The disk was rotated underneath the diamond pin. A normal applied load of 5N and 10 minutes testing time was used for various wear track diameters. Qualitative observation showed that the multilayered coatings of the present invention exhibited better wear resistance to the diamond pin than the prior art, See FIG. 8.

### Example 10

Two samples of the multilayer coating (Multilayer #1 and #2) of the present invention of Table 1 were compared for surface smoothness to samples of the prior art coatings of Table 1 and two conventional PVD TiN coatings. Surface texture maps of the samples were obtained using Wyko RST—Vertical scanning interferometry techniques. Table 2 denotes the statistical parameters derived from the interferometry measurements for the various samples. The manner of data collection for XslopeRq gathers more information relating to slopes on the surface than the other statistical parameters shown below.

TABLE 2
Wyko 3D surface texture analysis: Grand Average

| | | | | | | | | | XSlope |
|---|---|---|---|---|---|---|---|---|---|
| | Ra | Rq | Rsk | Rku | Rz | Rp | Rt | Rpk | Rq |
| Coating | nm | nm | nm | nm | nm | nm | nm | nm | (mrad) |
| Multilayer | 252 | 314 | −0.32 | 2.94 | 2023 | 1036 | 2305 | 165 | 189 |
| #1 | | | | | | | | | |
| Multilayer | 265 | 331 | −0.28 | 3.06 | 2460 | 1636 | 3018 | 178 | 198 |
| #2 | | | | | | | | | |
| Monolayer | 282 | 355 | −0.25 | 3.12 | 2516 | 1430 | 2929 | 217 | 282 |
| TiN | | | | | | | | | |
| *Polished- | 579 | 930 | 1.44 | 13.0 | 10280 | 9269 | 13439 | 1873 | 289 |
| Bilayer | | | | | | | | | |
| TiCN/TiN | | | | | | | | | |
| PVD TiN | 113 | 153 | −1.04 | 5.34 | 1341 | 639 | 1647 | 81 | 129 |
| #1 | | | | | | | | | |
| PVD TiN | 240 | 300 | −0.31 | 3.77 | 2200 | 2109 | 3437 | 130 | 200 |
| #2 | | | | | | | | | |

*Surface polished on honed edges only after coating.

The XslopeRq parameter is a better indicator of the asperities and slopes of the surface crystallites of coatings and better differentiates the surface roughness of the samples compared to Ra. The lower the value for XslopeRq, the smoother the surface.

The results in Table 2 show that the TiCN/TiN multilayered CVD coatings of the present invention approach the surface smoothness of PVD TiN coated samples and exhibit smoother surfaces as compared to polished bilayer CVD TiCN/TiN and unpolished monolayer TiN coated samples. Smoother as-coated surfaces allow the elimination of labor intensive and time-consuming polishing steps, and provides greater efficiencies in production and a more uniform product.

FIGS. 4a, 4b and 4c show photomicrographs of the coatings of Table 1. These surface photos reveal the morphology of TiN influenced by supporting layers of the underlying coatings described in Example 5. The grain size of the underlying layers can be correlated to this surface morphology. FIG. 4a shows the multilayered coating of the present invention. FIG. 4b shows the monolayer TiN coating of the prior art. The monolayered TiN coated sample reveals coarser crystallites typical of CVD TiN. It is also typical for thick monolayer coatings to exhibit grain coarsening if growth is not interrupted and renucleated as in the case of multilayer films. FIG. 4c shows the bilayer TiCN/TiN coating of the prior art. In FIG. 4a, the grain size was extremely fine as compared to the monolayer TiN and bilayer TiCN/TiN coatings of the prior art (4b and 4c).

FIG. 5 is a graph comparing the hardness profile of two multilayers according to the present invention with that of the prior art coatings of Table 1. Hardness measurements in the range of displacement of 20 to 110 nm for each sample were compared. Hardness for the prior art of Table 1 averaged 22 Giga Pascal (GPa) for the bilayer TiCN/TiN and 34 GPa for the monolayer TiN coating. Hardness measurements for the multilayered coating of the present invention described in Table 1 averaged approximately 40 Gpa. For the same range of displacement (20-110 nm), the “Higher carbon multilayer” coating of the present invention averaged approximately 45 GPa, which was considerably higher than the hardness measurements for the prior art coatings. Close to the surface, the higher carbon multilayer achieved levels as high as 57 GPa. A gradual decline in hardness and elastic modulus values with penetration into the coating is typically observed for most thin film hard coatings due to density variations through the coating, porosity effects, increased substrate effects at higher penetrations and other sample preparation and nanoindentation measuring device effects. FIG. 6 is a graph comparing the elastic modulus of the invention with the prior art from the same indentations. The elastic modulus profile of the multilayered coated samples fall in line with the hardness profile confirming that these two properties are complimentary. Higher scatter in the elastic modulus profiles is thought to be related to the effect of density (porosity) on the modulus measurements. Both hardness and elastic modulus for the coatings of the present invention are improved compared to the prior art. Higher hardness and elastic modulus in thin coatings contribute significantly toward abrasion resistance of the coating in coated tools that are used for machining of abrasive materials. The higher hardness values of the multilayered coatings are thought to be at least partly attributable to the extremely fine grain structure achieved by stratifying the layers under the conditions of rapid cycling of reactants, minimizing the chances for grain growth.

FIGS. 7a and 7b are graphs comparing the flank wear of the invention with the prior art under different machining conditions. The slope of the wear curve for a particular sample is an indicator of flank wear resistance. The lower the slope, the better the resistance to wear. As shown by relative slopes of the flank wear curves for each sample, the coatings of the present invention are more resistant to flank wear than the prior art.

FIG. 8 is a graph correlating wear volume with coating thickness using a diamond pin on disk wear test. The results of this test allow graphical comparison of the relative abrasion resistance of coatings of the present invention with coatings of the prior art. The lower the amount of wear volume, for a particular coating substance and thickness, the better its resistance to abrasive wear. As shown by FIG. 8, the present invention has significantly better wear resistance, even at low coating thicknesses, than even the thickest conventional CVD tested.

It is submitted that the foregoing results show that articles and, in particular cutting tools, according to the present invention exhibit an excellent combination of smoothness, hardness, toughness, friction coefficients and wear resistance properties. Cemented carbide articles which have been coated according to the present invention may also be subjected to known carburization treatments. It is also within the scope of the invention to apply the multilayered coatings of the present invention underlying or overlaying other known coatings or layers.

It is intended that the specification and examples be considered as exemplary only. Other embodiments of the invention, within the scope and spirit of the following claims will be apparent to those of skill in the art from practice of the invention disclosed herein and consideration of this specification. All documents referred to herein are incorporated by reference hereby.

What is claimed is:

1. An article of manufacture comprising:
a hard wear resistant substrate, a CVD coating bonded to said substrate, said CVD coating comprised of a first system of at least two different substances deposited in individual layers comprising at least approximately 50 layers, wherein each of said layers has a thickness of less than 200 nanometers.

2. The article of manufacture of claim 1 wherein said at least two different substances are selected from the group consisting of Al2O3, ZrO2, Y2O3, AlN, cBN and nitrides, carbides and carbonitrides of metals of Groups IVa and Va.

3. The article of manufacture of claim 2 wherein said CVD coating further comprises a second system of at least two different substances deposited in individual layers, each layer comprising at least one substance selected from the group consisting of Al2O3, ZrO₂, Y2O3, AlN, cBN and nitrides, carbides and carbonitrides of metals of Groups IVa and Va; wherein said second system is comprised of at least one substance different from said first system.

4. The article of manufacture of claim 1 wherein said CVD coating has a hardness of at least approximately 40 GPa.

5. The article of manufacture of claim 1 wherein said individual layers form a first system of individual layers, each layer having a thickness of 20-190 nm.

6. The article of manufacture of claim 1 wherein at least two different substances form a composite structure of at least two separately identifiable phases.

7. An article of manufacture comprising:
a hard wear resistant substrate, a CVD coating bonded to said substrate, said CVD coating having a thickness of 0.5 to 20 microns and comprised of a plurality of layers, each of said layers having a thickness of 200 nanometers or less, wherein said CVD coating has a hardness of at least approximately 40 GPa.

8. The article of manufacture of claim 7 wherein the CVD coating has a smoothness value of XslopeRq of 200 or less.

9. The article of manufacture of claim 7 wherein said plurality of layers comprises at least two different individual CVD layers, each layer comprising at least one substance selected from the group consisting of Al2O3, ZrO2, Y2O3, AlN, cBN and nitrides, carbides and carbonitrides of metals of Groups IVa and Va.

10. The article of manufacture of claim 9 wherein one of said at least two different individual CVD layers comprises at least one substance selected from the group consisting of nitrides, carbides or carbonitrides of titanium, and a second one of said at least two different individual CVD layers comprises at least one oxide of at least one element selected from the group consisting of Al and Zr; said at least one substance and said at least one oxide being alternately deposited as CVD coatings in the form of layers wherein each layer of said substance and said oxide has a thickness of less than 200 nanometers.

11. The article of manufacture of claim 9 wherein said at least two different individual CVD layers comprise alternating layers of TiCN and TiN.

12. A CVD method of applying a multilayered coating having ultrathin layers to a hard wear resistant article comprising the steps of:
a) heating the article to approximately 800-1200° C. in an atmosphere comprising hydrogen and nitrogen;
b) depositing a first system at least two different individual CVD layers, each layer comprising at least one substance selected from the group consisting of Al2O3, ZrO2, Y2O3, AlN, cBN and nitrides, carbides and carbonitrides of metals of Groups IVa and Va;
c) controlling coating deposition temperatures, times, flow rates and quantity of reactants delivered per unit time whereby each of said CVD layers comprise a thickness of less than 200 nm; and
d) repeating said steps b and c approximately 25 to 200 times.

13. The CVD method of claim 12 wherein said coating deposition temperature is held substantially within ±20° C. of a selected coating deposition temperature.

14. The CVD method of claim 12 wherein said quantity of reactants delivered per unit time is at least 80% of a selected flow rate for said reactants for the coating deposition process.

15. The CVD method of claim 12 wherein said CVD layers are deposited to form individual layers having a thickness of 20-190 nm.

16. The CVD method of claim 12 wherein said CVD layers are deposited to form a composite structure of at least two separately identifiable phases.

17. The CVD method of claim 12 wherein one of said at least two CVD layers comprises at least one substance selected from the group consisting of nitrides, carbides and carbonitrides of metals of Groups IVa and Va.

18. The CVD method of claim 12 wherein one of said at least two CVD layers comprises at least one substance selected from the group consisting of Al₂O₃, ZrO₂, Y₂O₃, AlN and cBN.

19. The CVD method of claim 12 wherein one of said at least two CVD layers comprises at least two co-deposited substances.

20. The CVD method of claim 12 further comprising depositing a second system of at least two different individual CVD layers, each layer comprising at least one substance selected from the group consisting of Al2O3, ZrO2, Y2O3, AlN, cBN and nitrides, carbides and carbonitrides of metals of Groups IVa and Va; wherein said second system is comprised of at least one substance different from said first system.
